(19) United States
(12) Patent Application Publication
(10) Pub. No.: US 2023/0005744 A1
(43) Pub. Date: Jan. 5, 2023

(54) FORMING STRUCTURES WITH BOTTOM-UP FILL TECHNIQUES

(71) Applicant: ASM IP Holding B.V., Almere (NL)

(72) Inventors: Caleb Miskin, Mesa, AZ (US); Omar Elleuch, Litchfield Park, AZ (US); Peter Westrom, Payson, AZ (US); Rami Khazaka, Leuven (BE); Qi Xie, Shanghai (CN); Alexandros Demos, Scottsdale, AZ (US)

(21) Appl. No.: 17/850,370

(22) Filed: Jun. 27, 2022

Related U.S. Application Data
(60) Provisional application No. 63/216,811, filed on Jun. 30, 2021.

(51) Int. Cl. H01L 21/02; C23C 16/455

(52) U.S. Cl. CPC H01L 21/02609; C23C 16/45557; H01L 21/02532; H01L 21/0259; H01L 29/42392

(57) ABSTRACT

A method of forming a structure includes supporting a substrate within a reaction chamber of a semiconductor processing system, the substrate having a recess with a bottom surface and a sidewall surface extending upwards from the bottom surface of the recess. A film is deposited within the recess and onto the bottom surface and the sidewall surface of the recess, the film having a bottom segment overlaying the bottom surface of the recess and a sidewall segment deposited onto the sidewall surface of the recess. The sidewall segment of the film is removed while at least a portion bottom segment of the film is retained within the recess, the sidewall segment of the film removed from the sidewall surface more rapidly than removing the bottom segment of the film from the bottom surface of the recess. Semiconductor processing systems and structures formed using the method are also described.

### CROSS-REFERENCE TO RELATED APPLICATIONS

This application is a non-provisional of, and claims priority to and the benefit of, U.S. Provisional Patent Application No. 63/216,811, filed Jun. 30, 2021 and entitled “FORMING STRUCTURES WITH BOTTOM-UP FILL TECHNIQUES,” which is hereby incorporated by reference herein.

### FIELD OF INVENTION

The present disclosure generally relates to forming structures. More particularly, the present disclosure relates to forming structures overlaying substrates using trench bottom-up fill techniques, such as during the fabrication of semiconductor devices.

### BACKGROUND OF THE DISCLOSURE

Films are commonly deposited onto substrates to form various types of structures during the fabrication of various types of semiconductors devices such as display devices, power electronics, and very large-scale integrated circuits. Deposition of such films is generally accomplished by positioning a substrate within a reactor, heating the substrate to a temperature suitable for deposition of a desired film onto the substrate, and flowing gas containing constituents of the desired film into the reactor. As the gas flows through the reactor and across the substrate the constituent forms a film on the substrate, typically at a rate and to thickness corresponding to the environmental conditions within the reactor and temperature of the substrate. The resulting film is generally conformal with the underlying substrate, the film typically depositing onto the topology of the substrate in a way that corresponds to the substrate topology.

During the fabrication of some semiconductor devices it may be necessary to deposit a film into the recess such a trench defined within the surface of the substrate. For example, during the fabrication transistor devices having two-dimensional or three-dimensional architectures, fill structures may be formed within trenches by depositing films having desired electrical properties within the trenches, such as isolation features formed to electrically separate adjacent transistors from one another. Such fill features may be formed using epitaxial techniques, the fill feature resulting from the progressive thickening of film from the bottom of the trench upwards and laterally inward from the opposing sidewalls of the trench. Film deposition typically continues until the trench closes—either by the film overlaying the trench bottom bridging the film overlying the sidewalls and overtopping the trench mouth or surfaces of the film overlaying the sidewall converging against one another within the trench.

In some fill structures, the interface (or seam) where opposing surfaces of the sidewall films and/or bottom surface film converge may influence the electrical properties of the resulting fill structure. For example, in substrates where the trench bottom presents a different crystalline structure to the trench than that presented by the trench sidewalls to the trench, film deposited on the trench bottom surface may develop with a different crystalline structure than that of film deposited onto the trench sidewalls. As a consequence, the crystalline structure within the fill structure may change at the interface of the opposing surfaces within the fill structure, locally increasing (or decreasing) electrical resistivity at the interface in relation to the remainder of the fill structure. While generally manageable, the localized variation in electrical properties at the interface can, in some semiconductor devices, influence reliability of the semiconductor device incorporating the fill structure.

Such systems and methods have generally been considered suitable for their intended purpose. However, there remains a need in the art for improved methods of forming structures using bottom-up fill techniques, semiconductor processing systems configured to form structures using bottom-up fill techniques, and semiconductor devices including structures formed using bottom-up fill techniques. The present disclosure provides a solution to this need.

### SUMMARY OF THE DISCLOSURE

A method of forming a structure is provided. The method includes supporting a substrate within a reaction chamber of a semiconductor processing system, the substrate having a recess with a bottom surface and a sidewall surface extending upwards from the bottom surface of the recess. A film is deposited within the recess and onto the bottom surface and the sidewall surface of the recess, the film having a bottom segment overlaying the bottom surface of the recess and a sidewall segment deposited onto the sidewall surface of the recess. The sidewall segment of the film is removed while at least a portion bottom segment of the film is retained within the recess, the sidewall segment of the film removed from the sidewall surface more rapidly than removing the bottom segment of the film from the bottom surface of the recess.

In addition to one or more of the features described above, or as an alternative, further examples of the method may include that the bottom segment of the film is deposited onto the bottom surface more rapidly than the sidewall segment of the film is deposited onto the sidewall surface of the recess.

In addition to one or more of the features described above, or as an alternative, further examples of the method may include that the sidewall segment and the bottom segment of the film are removed at a removal rate ratio that is between about 5:1 and about 25:1.

In addition to one or more of the features described above, or as an alternative, further examples of the method may include that the bottom segment and the sidewall segment of the film are deposited at a deposition rate ratio that is between about 1.1:1 and about 2:1.

In addition to one or more of the features described above, or as an alternative, further examples of the method may include that the sidewall segment and the bottom segment of the film are removed at a predetermined removal pressure that is between about 1 torr and about 50 torr.

In addition to one or more of the features described above, or as an alternative, further examples of the method may include that the sidewall segment and the bottom segment of the film are removed at a predetermined removal temperature that is between about 675° C. and about 800° C.

In addition to one or more of the features described above, or as an alternative, further examples of the method may include that the sidewall segment and the bottom segment of the film are deposited at a predetermined deposition pressure that is between about 1 torr and about 50 torr.

In addition to one or more of the features described above, or as an alternative, further examples of the method may include that the sidewall segment and the bottom segment of the film are deposited at a predetermined deposition temperature that is between about 675° C. and about 800° C.

In addition to one or more of the features described above, or as an alternative, further examples of the method may include that the sidewall segment and the bottom segment of the film are deposited and removed at a common pressure, wherein the sidewall segment and the bottom segment of the film are deposited and removed at a common temperature.

In addition to one or more of the features described above, or as an alternative, further examples of the method may include flowing dichlorosilane (DCS), hydrochloric acid (HCl), and hydrogen (H₂) gas through an interior of the reaction chamber to deposit the sidewall segment and the bottom segment of the film into the recess.

In addition to one or more of the features described above, or as an alternative, further examples of the method may include flowing hydrochloric acid (HCl) and hydrogen (H₂) gas through an interior of the reaction chamber to remove the sidewall segment and a portion of the bottom segment of the film from within the recess.

In addition to one or more of the features described above, or as an alternative, further examples of the method may include that the bottom surface of the recess has a silicon 1 0 0 crystalline structure and that the sidewall surface of the recess has a silicon 1 1 0 crystalline structure.

In addition to one or more of the features described above, or as an alternative, further examples of the method may include that the deposition operation and the removal operation are a first deposition/removal cycle, and that the method further includes one or more second deposition/removal cycle.

In addition to one or more of the features described above, or as an alternative, further examples of the method may include filling the recess bottom-up from the bottom surface of the recess to an opening into the recess.

In addition to one or more of the features described above, or as an alternative, further examples of the method may include exposing the sidewall surface above a retained portion of the bottom segment of the film from within the recess.

A semiconductor processing system is provided. The semiconductor processing system includes a reaction chamber, a gas delivery system connected to the reaction chamber, and a controller. The controller is operatively connected to the gas delivery system and the reaction chamber and is responsive to instructions recorded on a non-transitory machine-readable memory to: support a substrate within the reaction chamber, wherein the substrate has a recess with a bottom surface and a sidewall surface extending upwards from the bottom surface of the recess; deposit a film within the recess and onto the bottom surface and the sidewall surface of the recess, the film having a bottom segment overlaying the bottom surface of the recess and a sidewall segment deposited onto the sidewall surface of the recess; and remove the sidewall segment of the film while retaining at least a portion bottom segment of the film within the recess, the sidewall segment of the film is removed from the sidewall surface of the recess more rapidly than the bottom segment of the film is removed from the bottom surface of the recess.

In addition to one or more of the features described above, or as an alternative, further examples of the system may include that the instructions further cause the controller to: flow hydrochloric acid (HCl) and hydrogen (H₂) gas through an interior of the reaction chamber to remove the sidewall segment and a portion of the bottom segment of the film from within the recess; flow dichlorosilane (DCS), hydrochloric acid (HCl), and hydrogen (H₂) gas through the interior of the reaction chamber to deposit the sidewall segment and the bottom segment of the film into the recess; and that the bottom segment of the film is deposited onto the bottom surface of the recess more rapidly than the sidewall segment of the film is deposited onto the sidewall surface of the recess.

In addition to one or more of the features described above, or as an alternative, further examples of the system may include that the instructions further cause the controller to: deposit the bottom segment and the sidewall segment of the film at a deposition rate ratio that is between about 1.1:1 and about 2:1; and remove the bottom segment and the sidewall segment of the film at a removal rate ratio that is between about 5:1 and about 25:1.

In addition to one or more of the features described above, or as an alternative, further examples of the system may include that the instructions further cause the controller to: deposit the sidewall segment and the bottom segment of the film at a predetermined deposition pressure that is between about 1 torr and about 50 torr; deposit the sidewall segment and the bottom segment of the film at a predetermined deposition temperature that is between about 675° C. and about 800° C.; remove the sidewall segment and a portion of the bottom segment of the film at a predetermined deposition pressure that is between about 1 torr and about 50 torr; and remove the sidewall segment and the portion of the bottom segment of the film at a predetermined deposition temperature that is between about 675° C. and about 850° C.

A semiconductor device structure is provided. The semiconductor device structure includes a finFET or gate-all-around transistor having a structure formed using the method as described above.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a semiconductor processing system in accordance with the present disclosure, showing a controller operatively associated with a reaction chamber to form a structure within a recess overlaying a substrate supported within the reaction chamber;

FIGS. 2-4 are a block diagram of a method of forming a structure overlaying a substrate using the semiconductor processing system of FIG. 1, showing operations of the method according to an illustrative and non-limiting example of the method;

FIGS. 5-10 are cross-sectional side views of a substrate, sequentially showing a structure being formed by filling a recess overlaying a substrate by cyclically depositing film within the recess and removing a sidewall segment of the film from within the recess;

FIGS. 11 and 12 are charts of film deposition rate ratios according to temperature to and pressure, showing the deposition rate ratio being constant within the deposition temperature range and increasing with decreasing pressure within the deposition pressure range; and

FIGS. 13 and 14 are charts of film removal rate ratios according to temperature to and pressure, showing the removal rate ratio being constant within the removal temperature range and increasing with decreasing pressure within the removal pressure range.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

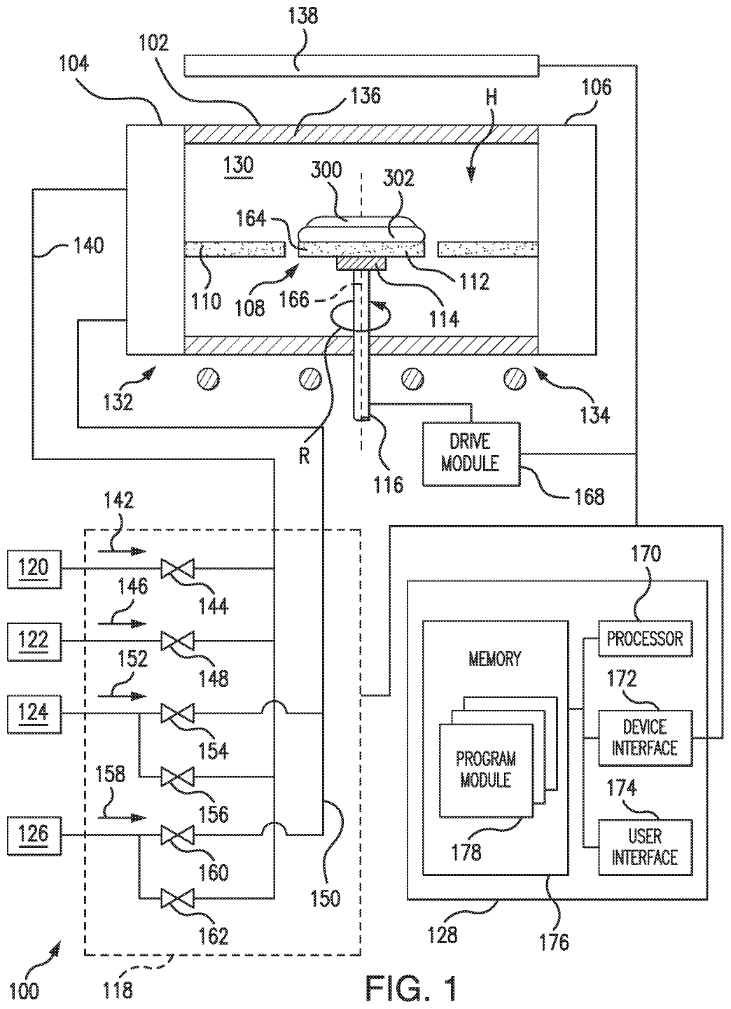

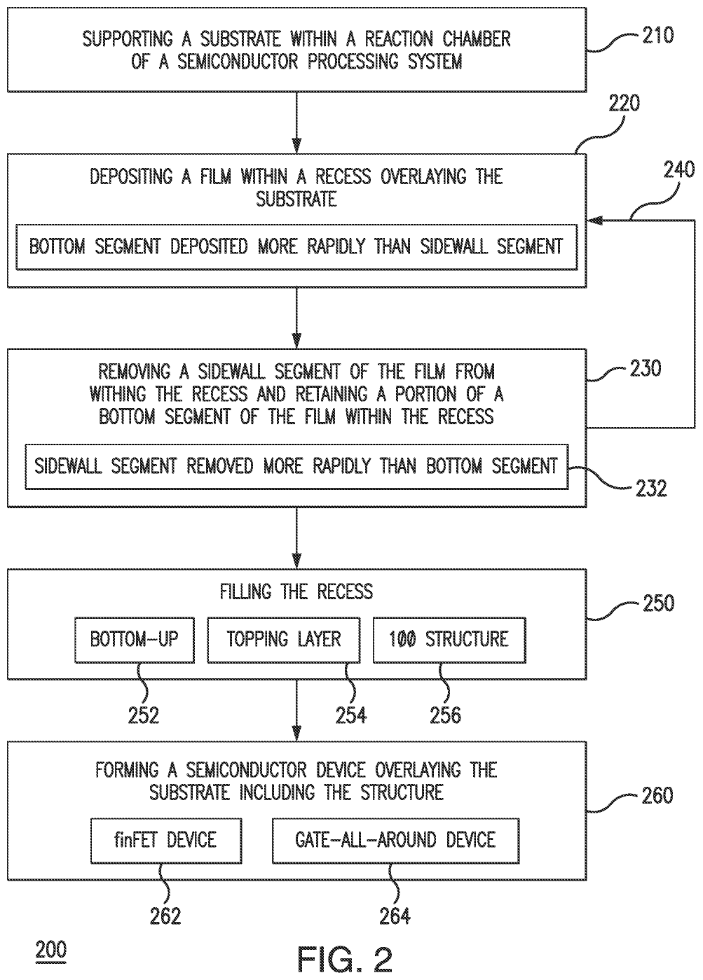

Reference will now be made to the drawings wherein like reference numerals identify similar structural features or aspects of the subject disclosure. For purposes of explanation and illustration, and not limitation, a partial view of an example of semiconductor processing system in accordance with the present disclosure is shown in FIG. 1 and is designated generally by reference character 100. Other examples of semiconductor processing systems, methods of forming structures, and structures formed using bottom-up fill techniques in accordance with the present disclosure, or aspects thereof, are provided in FIGS. 2-14, as will be described. The systems and methods of the present disclosure may be used to form semiconductor devices, such as three-dimensional transistor devices having finFET or gate-all-around architectures, though the present disclosure is not limited to any particular architecture or semiconductor device in general.

Referring to FIG. 1, the semiconductor processing system 100 is shown. The semiconductor processing system 100 includes a reaction chamber 102 with an injection header 104 and an exhaust header 106. The semiconductor processing system also includes a process kit 108 with an outer ring 110, a susceptor 112, a susceptor support member 114, and shaft 116. The semiconductor processing system 100 further include a gas delivery arrangement 118 with a first precursor source 120, a second precursor source 122, a halide source 124, and a purge/carrier gas source 126. The semiconductor processing system 100 additionally includes a controller 128. Although a particular type of reaction chamber is shown in FIG. 1 and described herein, e.g., a crossflow-type reaction chamber, it is to be understood and appreciated that semiconductor processing systems having other types of reaction chambers such as downflow-type reaction chambers, may also benefit from the present disclosure.

The reaction chamber 102 has a hollow interior 130 that extends between an injection end 132 and an exhaust end 134 of the reaction chamber 102, and is formed from a transmissive material 136. The transmissive material 136 may include a glass material, such as quartz. One or more heater elements 138 may be arranged outside of the reaction chamber 102. The one or more heater elements 138 may be configured to communicate heat H into the interior 130 of the reaction chamber 102 through the transmissive material 136 forming the reaction chamber 102, the transparent material 136 radiantly coupling the one or more heater elements 138 the interior 130 of the reaction chamber 102 in such examples. The one or more heater element 138 is in turn operably associated with the controller 128.

The exhaust header 106 is connected to the exhaust end 134 of the reaction chamber 102 and is configured to connect the interior 130 of the reaction to an exhaust source such as a scrubber. In certain examples, the exhaust end 134 of the reaction chamber 102 may have an exhaust flange extending thereabout, the exhaust header 106 in such examples connected to the exhaust flange. The injection header 104 is connected to the injection end 132 of the reaction chamber 102. It is contemplated that the injection header 104 connect the gas delivery arrangement 118 to the reaction chamber 102. In this respect the injection header 104 connects each of the first precursor source 120, the second precursor source 122, the halide source 124, and the purge/carrier gas source 126 to the reaction chamber 102 in the illustrated examples. In certain examples, the injection end 132 of the reaction chamber 102 may have an injection flange extending thereabout, and the injection header 104 may be connected to the injection flange. The reaction chamber 102 may be as shown and described in U.S. Patent Application Publication No. 2018/0363139 A1 to Rajavelu et al., filed Apr. 25, 2018, the contents of which are incorporated herein by reference in their entirety.

The first precursor source 120 is connected to the injection header 104 by a precursor conduit 140 and is configured to provide a first precursor 142 to the reaction chamber 102. In certain examples, the first precursor 142 may include a silicon-containing precursor, such as a hydrogenated silicon-containing precursor and/or a chlorinated silicon-containing precursor. Examples of suitable chlorinated silicon-containing precursors include monochlorosilane (MCS), dichlorosilane (DCS), trichlorosilane (TCS), hexachlorodisilane (HCDS), octachlorotrislane (OCS), and silicon tetrachloride (STC). Examples of suitable hydrogenated silicon-containing precursors include silane (SiH₄), disilane (Si₂H₆), trisilane (Si₃H₈), and tetrasilane (Si₄H₁₀). It is contemplated that a first precursor mass flow controller (MFC) 144 connect the first precursor source 120 to the precursor conduit 140. The first precursor MFC 144 may be operatively associated with the controller 128 to flow the first precursor 142 to the injection header 104, and therethrough into the interior 130 of the reaction chamber 102.

The second precursor source 122 is also connected to the injection header 104 by the precursor conduit 140 and is configured to provide a second precursor 146 to the reaction chamber 102. In certain examples, the second precursor 146 may include a germanium-containing precursor. Examples of suitable germanium-containing precursors include germane (GeH₄), digermane (Ge₂H₆), trigermane (Ge₃H₈), and germylsilane (GeH₆Si). In accordance with certain examples, the second precursor 146 may include an n-type or a p-type dopant. Examples of suitable n-type dopants include phosphorus (P) and arsenic (As). Examples suitable p-type dopants include boron (B), gallium (Ga) and indium (In). It is contemplated that a second precursor MFC 148 connect the second precursor source 122 to the precursor conduit 140. The second precursor MFC 148 may be operatively associated with the controller 128 to control flow of the second precursor 146 to the injection header 104, and therethrough into the interior 130 of the reaction chamber 102.

In the illustrated example, the halide source 124 is connected to the injection header 104 by both the precursor conduit 140 and a halide conduit 150 and is configured to provide a halide 152 to the reaction chamber 102. The halide 152 may include fluorine (F) or chlorine (Cl), for example by providing a flow of hydrochloric acid (HCl) to the reaction chamber 102. It is contemplated that a first halide MFC 154 connect the halide source 124 to the precursor conduit 140 and therethrough to the reaction chamber 102 through the injection header 104, and that a second halide MFC 156 also connect the halide source 124 to the halide conduit 150 and therethrough to the reaction chamber 102 through the injection header 104. The first halide MFC 154 and the second halide MFC 156 are in turn operatively associated with the controller 128 to control flow of the halide 152 through either (or both) the precursor conduit 140 and the halide conduit 150, respectively. As will be appreciated by those of skill in the art in view of the present disclosure, this allows the halide source 124 to flow the halide 152 into the reaction chamber 102 with the first precursor 142 and/or the second precursor 146 and/or independently of first precursor 142 and/or the second precursor 146.

The purge/carrier gas source 126 is connected to the injection header 104 by the precursor conduit 140 and the halide conduit 150 and is configured to provide a purge/carrier gas 158 to the reaction chamber 102. Examples of suitable purge/carrier gases include hydrogen (H₂), nitrogen (N₂), helium (He), krypton (Kr), argon (Ar), and mixtures thereof. It is contemplated that a first purge/carrier gas MFC 160 connect the purge/carrier gas source 126 to the precursor conduit 140 and therethrough the reaction chamber 102 through the injection header 104, and that a second purge/carrier gas MFC 162 further connect the purge/carrier gas source 126 to the halide conduit 150 and therethrough to the reaction chamber 102 through the injection header 104. The first purge/carrier gas MFC 160 and the second purge/carrier gas MFC 162 are in turn operatively associated with the controller 128 to control flow the purge/carrier gas 158 into the reaction chamber 102. As will be appreciated by those of skill in the art in view of the present disclosure, this allows the purge/carrier gas 158 to be provided to the reaction chamber 102 through either (or both) the precursor conduit 140 and the halide conduit 150. In certain examples, the gas delivery arrangement 118 may be as shown and described in U.S. Patent Application Publication No. 2020/00404458 A1 to Ma et al., filed Aug. 6, 2018, the contents of which is incorporated herein by reference in its entirely. However, as will be appreciated by those of skill in the art in view of the present disclosure, gas delivery arrangements employing one or more manual flow control valve may also be employed and remain within the scope of the present disclosure.

The outer ring 110 is fixed within the interior 130 of the reaction chamber 102. The outer ring 110 may be formed from an opaque material 164 to receive heat H from one or more heater element 138. Examples of suitable opaque materials include silicon carbide coated graphite. It is contemplated that the outer ring 110 have an aperture therein arranged to receive therein the susceptor 112, the susceptor 112 circumferentially separated from the outer ring 110 by a gap.

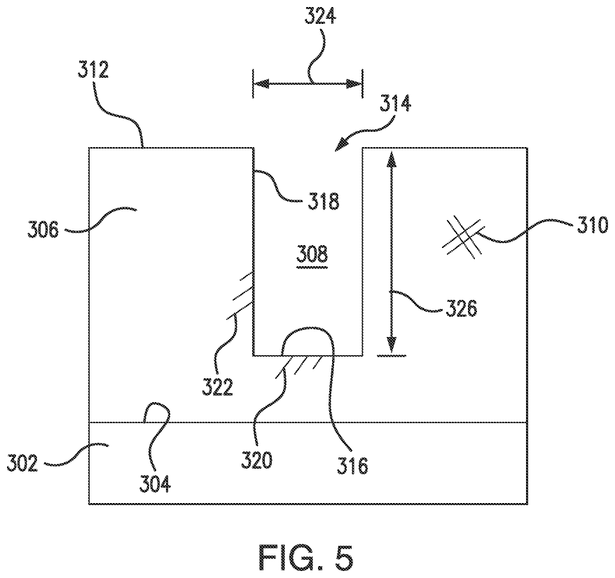

The susceptor 112 is arranged within the interior 130 of the reaction chamber 102 and within the outer ring 110 and is configured to support thereon a substrate 302 during the forming of a structure 300 within a recess 308 (shown in FIG. 5) overlaying the substrate 302. In this respect it is contemplated that the outer ring 110 extend circumferentially about the susceptor 112, and that the susceptor 112 also be formed from the opaque material 164 to receive heat H communicated by the one or more heater element 138, e.g., directly or indirectly from the outer ring 110. It is contemplated that the susceptor 112 further be arranged along a rotation axis 166 and fixed in rotation about the rotation axis 166 to the susceptor support member 114. The susceptor support member 114 in turn couples the susceptor 112 to the shaft 116 and is fixed in rotation about the rotation axis 166 relative to the shaft 116. The shaft 116 is supported from rotation R about the rotation axis 166 and is operably associated with a drive module 168 to rotate the substrate 302 about the rotation axis 166 within the interior 130 of the reaction chamber 102 during the forming of the structure 300 within the recess 308 overlaying the substrate 302. The drive module 168 in turn is operably associated with the controller 128.

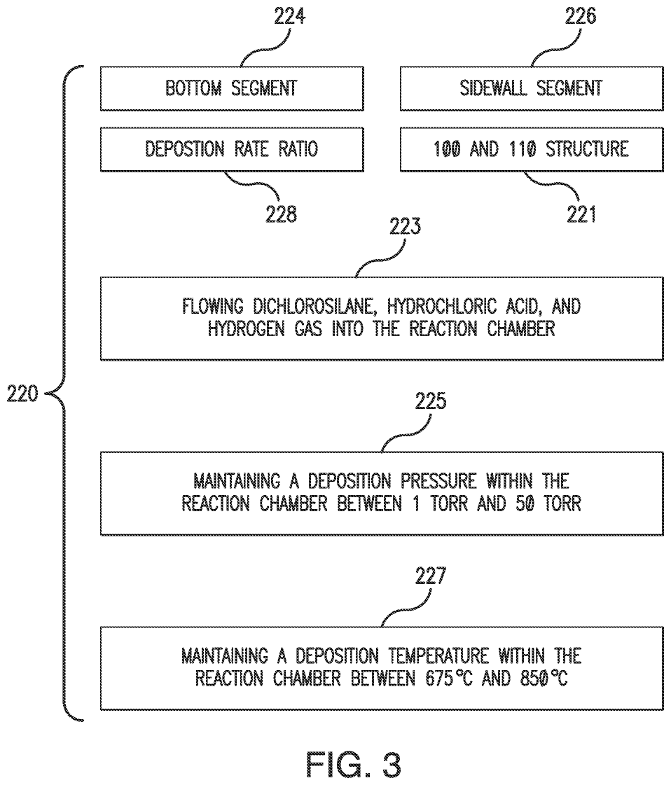

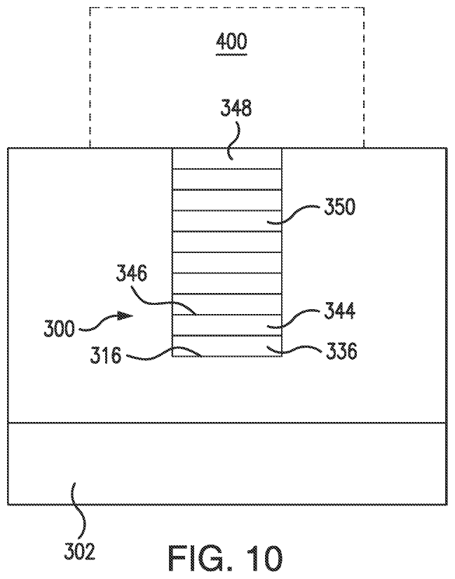

The controller 128 includes a processor 170, a device interface 172, a user interface 174, and a memory 176. The device interface 172 operably associates the controller 128 with the semiconductor processing system 100, e.g., via a wired or wireless link to one or more of the one or more heater element 138; one or more of the MFCs of the semiconductor processing system 100, e.g., the first precursor MFC 144, the second precursor MFC 148, the first halide MFC 154 and the second halide MFC 156, and the first purge/carrier gas MFC 160 and the second purge/carrier gas MFC 162; and the drive module 168. The processor 170 is in turn operably connected to the user interface 174, which may include a display and/or a user input device and is disposed in communication with the memory 176. The memory 176 has a plurality of program modules 178 recorded thereon that, when read by the processor 170, cause the processor 170 to execute certain operations. Among the operations are operations of a method 200 (shown in FIGS. 2 and 3) of forming a structure, e.g., a structure 300 (shown in FIG. 10), overlaying a substrate supported on the susceptor 112.

With reference to FIGS. 2-4, the method 200 is shown. As shown with box 210, the method 200 begins by supporting a substrate, e.g., the substrate 302 (shown in FIG. 1), within a reaction chamber of a semiconductor processing system, e.g., the reaction chamber 102 (shown in FIG. 1) of the semiconductor processing system 100 (shown in FIG. 1). It is contemplated that the substrate have a recess overlaying the substrate, e.g., a recess 308 (shown in FIG. 5). It is also contemplated that the recess have a bottom surface and a sidewall surface, e.g., a bottom surface 316 (shown in FIG. 5) and a sidewall surface 318 (shown in FIG. 5). It is further contemplated that the bottom surface have a silicon 1 0 0 crystalline structure, e.g., a silicon 1 0 0 crystalline structure 320 (shown in FIG. 5), and that the sidewall surface have a silicon 1 1 0 crystalline structure, e.g., a silicon 1 1 0 crystalline structure 322 (shown in FIG. 5).

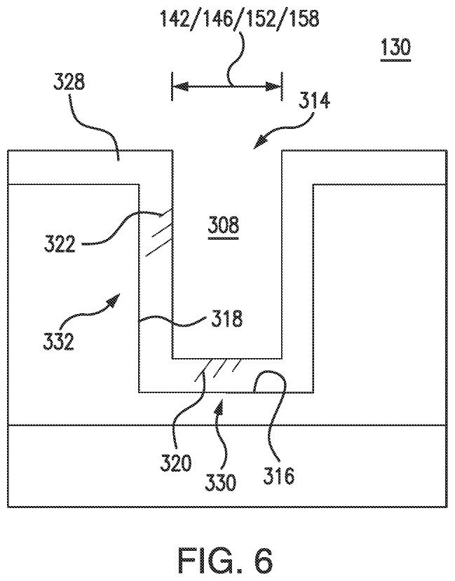

As shown with box 220, a film, e.g., a film 328 (shown in FIG. 6), is deposited within the recess overlaying the substrate. In certain examples, the bottom segment of the film may be deposited onto the bottom surface of the recess more rapidly than the sidewall segment is deposited onto the sidewall surface of the recess, as shown with box 222. As will be appreciated by those of skill in the art in view of the present disclosure, depositing the bottom segment onto the bottom surface more rapidly than the sidewall segment onto the sidewall surface may reduce the cycle time required to fill the recess, improving throughput of the semiconductor processing system employed to form the structure.

With reference to FIG. 3, depositing 220 the film within the recess may include only partially filling the recess. In this respect the film may be deposited such that the recess is partially filled with the bottom segment of the film and the sidewall segment of the film, as shown with box 224 and box 226. It is contemplated that the bottom segment and the sidewall segment be deposited at a bottom segment deposition rate-to-sidewall segment deposition rate ratio (i.e. a deposition rate ratio). In certain examples, the deposition rate ratio may be between about 1.1:1 and about 2:1. It is also contemplated that the bottom segment of the film have a crystalline structure that is different than the crystalline structure of the sidewall segment of the film. For example, in accordance with certain examples, the bottom segment of the film may have a 1 0 0 crystalline structure and the sidewall segment of the film may have a 1 1 0 crystalline structure, as shown with box 221.

As shown with box 223, depositing 220 the film may include flowing dichlorosilane (DCS), hydrochloric acid (HCl), and hydrogen (H₂) gas into the interior of the reaction chamber, e.g., using the gas delivery arrangement 118 (shown in FIG. 1). In certain examples, a predetermined deposition pressure may be maintained within the reaction chamber during the deposition of the film within the recess, as shown with box 225. It is contemplated that the predetermined deposition pressure may be between about 1 torr and about 50 torr during the depositing 220 operation, as also shown with box 225. For example, pressure within the interior of the reaction chamber may be maintained at less than about 50 torr, or less than about 40 torr, or less than about 30 torr, or less than about 20 torr, or even less than about 10 torr during the depositing operation, as shown with box 225. The predetermined deposition pressure may be about 1 torr.

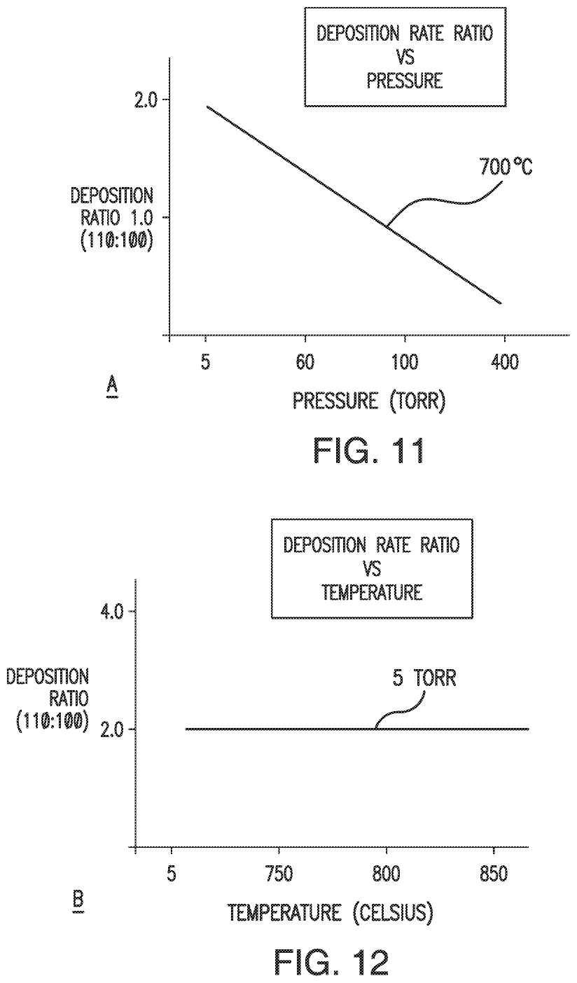

As shown with box 227, a predetermined deposition temperature may be maintained within the interior of the reaction chamber during the deposition 220 operation. The predetermined deposition temperature may be between about 675° C. and about 850° C. during the depositing 220 operation, as also shown with box 227. For example, the predetermined deposition temperature may be less than about 850° C., or less than 800° C., or less than about 750° C., or even less than about 675° C. during the depositing 220 operation, as also shown with box 227. Advantageously, flowing dichlorosilane (DCS), hydrochloric acid (HCl), and hydrogen (H₂) gas within these pressure and temperature ranges allows the bottom segment of the film to be deposited onto the bottom surface of the recess more rapidly than the sidewall segment of the film is deposited onto the sidewall surface of the recess in examples where the bottom surface of the recess has a silicon 1 0 0 crystalline structure and the lower surface of the recess has a silicon 1 1 0 crystalline structure, as shown with chart A in FIG. 11 and with chart B in FIG. 12.

With continuing reference to FIG. 2, once the film is deposited within the recess, the sidewall segment of the film is thereafter removed from the sidewall surface of the recess while at least a portion of the bottom segment of the film is retained within the recess, as shown with box 230. In certain examples, the sidewall segment of the film may be removed from the sidewall surface of the recess more rapidly than the bottom segment of the film from the bottom surface of the recess. As will be appreciated by those of skill in the art in view of the present disclosure, removing the sidewall segment of the film more rapidly from the sidewall surface of the recess than the bottom segment from the bottom surface of the recess may also reduce the cycle time required to fill the recess, also improving throughput of the semiconductor processing system employed to form the structure.

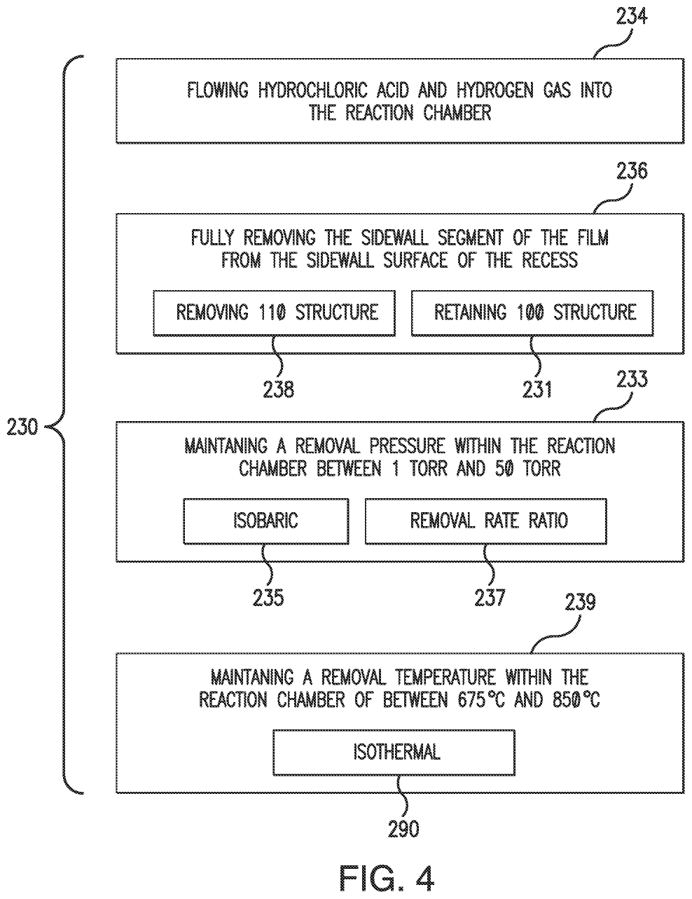

With reference to FIG. 4, removing 230 the sidewall segment of the film while retaining at least a portion of the bottom segment of the film may include flowing hydrochloric acid (HCl) and hydrogen (H₂) gas into the interior of the reaction chamber, as shown with box 234. In accordance with certain examples, removing 230 the sidewall segment while retaining at least a portion of the bottom segment of the film within the recess may include fully removing the sidewall segment of the film from the sidewall surface of the recess, as shown with box 236. In examples where the bottom surface of the recess has a silicon 1 0 0 crystalline structure and the sidewall surface of the recess has a silicon 1 1 0 crystalline structure, substantially all film having a 1 1 0 crystalline structure may be removed from the recess and a portion of the film having a 1 0 0 crystalline structure is retained within the recess, as shown with box 238 and box 231.

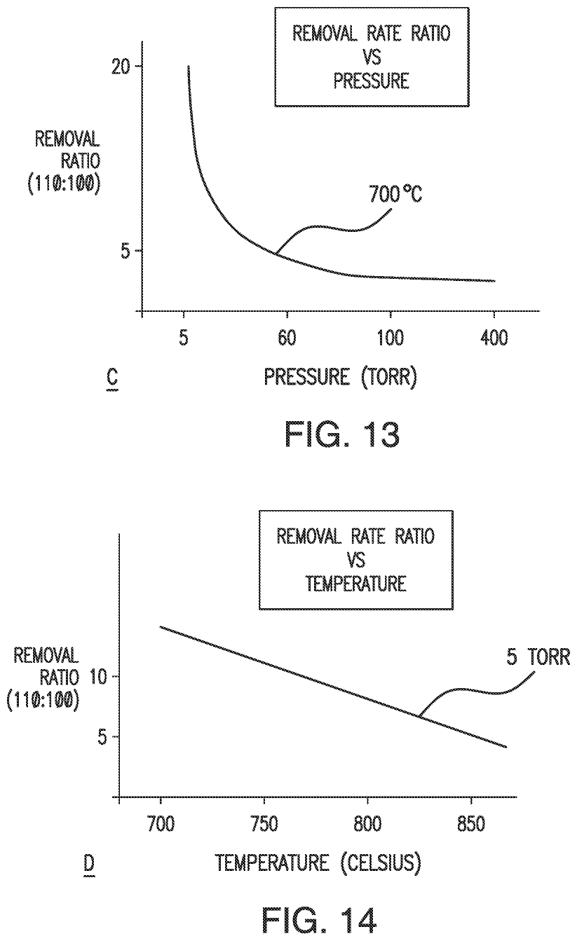

In certain examples, removing 230 the sidewall segment of the film while retaining at least a portion of the bottom segment of the film may include maintaining a predetermined removal pressure within the interior of the reaction chamber, as shown with box 233. Pressure may be maintained within the interior of the reaction chamber between about 1 torr and about 50 torr during the removing operation, as also shown with box 233. For example, pressure within the interior of the reaction chamber may be maintained at less than about 50 torr, or less than about 40 torr, or less than about 30 torr, or less than about 20 torr, or even less than about 10 torr, as shown with box 235. Advantageously, pressures within this range allows the sidewall segment of the film to be removed more rapidly than the bottom segment of the film, as shown with chart C in FIG. 13. Moreover, the removal rate ratio increases according to an exponential function with decreasing pressure, e.g., at pressures of about 2 torr, providing unexpected advantage at these pressures with respect to cycle time and throughput. In this respect, the removing operation may include removing the film with a removal rate ratio greater than about 5:1, or greater than about 10:1, or greater than about 15:1, or even greater than about 20:1, as shown with box 237. The removal rate ratio may be between about 5:1 and about 25:1, as also shown with box 237. As shown with box 235, the depositing and removing operations may be done at a common deposition pressure and removal pressure, the deposition and removal operations being isobaric in this respect.

In certain examples, removing the sidewall segment of the film while retaining at least a portion of the bottom segment of the film may include maintaining a predetermined removal temperature within the interior of the reaction chamber, as shown with box 239. For example, temperature within the interior of the reaction chamber may be maintained at less than about 850° C., or less than about 800° C., or less than about 750° C., or even less than about 675° C., as also shown with box 239. Temperature within the interior of the reaction chamber may be maintained between about 850° C. and about 675° C. during the removing operation, as further shown with box 239. Advantageously, temperatures within this range may further increase the removal rate ratio during the removing operation, as shown with chart D in FIG. 14. As shown with box 290, the depositing operation and the removing operation may be done at a common deposition temperature and removal temperature, the deposition and removal operations being isothermal in this respect. Notably, as shown in chart B in FIG. 12, the deposition rate ratio is relatively insensitive to temperature and the deposition temperature may therefore be selected according to a desired removal rate ratio within this temperature range.

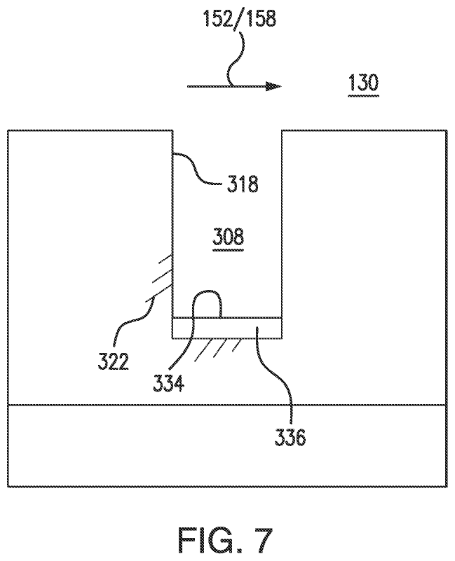

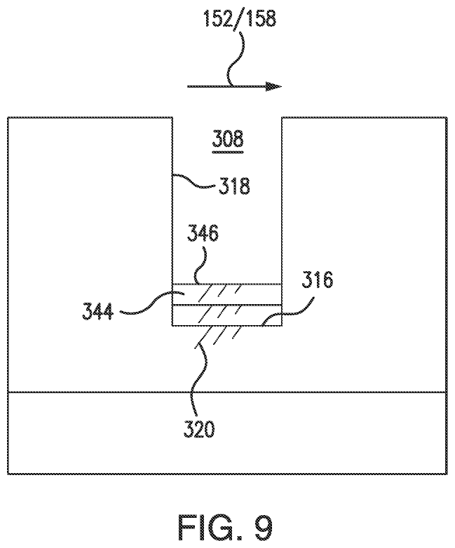

With continuing reference to FIG. 2, the depositing operation and the removing operation may be a first depositing/removing cycle employed to deposit a first retained portion of the film within the recess, e.g., a first retained portion 336 (shown in FIG. 7), and the method may include one or more second depositing/removal cycle, as shown with arrow 240. It is contemplated that the at least one second depositing/removing cycle be employed to deposit at least one second retained portion within the recess and overlaying the first retained portion, e.g., a second retained portion 344 (shown in FIG. 9), the first retained portion and the second retained portion forming a portion of the structure formed with the method 200, as also shown with arrow 240.

As shown with box 250, the method 200 may include filling the recess. In this respect the recess may be bottom-up filled, i.e., without incorporating film deposited onto the sidewall of the recess into the retained portions forming the structure, as shown with box 252. Completion of the fill may be accomplished in a topping operation during which a topping film is deposited onto the at least one second retained portion, as shown with box 254. It is contemplated that each of the retained portions have a homogenous 1 0 0 crystalline structure, the structure having a homogenous 1 0 0 crystalline structure throughout, i.e. without internal converging surfaces and/or portions formed with 1 1 0 crystalline structure, as shown with box 256. As will be appreciated by those of skill in the art in view of the present disclosure, the homogenous 1 0 0 crystalline structure limits variation of the electrical properties of the structure, improving reliability of semiconductor devices including structures formed using the method.

In certain examples, a semiconductor device, e.g., a semiconductor device 400 (shown in FIG. 10), may be formed overlaying the substrate that includes the structure, as shown with box 260. In certain examples, the semiconductor device may be a finFET semiconductor device, as shown with box 262. In accordance with certain examples, the semiconductor device may be a gate-all-around semiconductor device, as shown with box 264.

With reference to FIGS. 5-10, an example structure 300 (shown in FIG. 10) is shown being formed according to the method 200. In the illustrated example, and as shown in FIG. 5, the substrate 302 has a surface 304 and a material layer 306 with a recess 308. The substrate 302 is formed from a semiconductor material and may, in certain examples, include a silicon wafer. The material layer 306 overlays the surface 304 of the substrate 302 and is formed from a silicon-containing material 310. The silicon-containing material 310 extends upwards from the surface 304 of the substrate 302 and an opening 314 leading into the recess 308. The recess 308 is bounded by bottom surface 316 and a sidewall surface 318 each defined by the silicon-containing material 310, the bottom surface 316 overlaying the substrate 302, and sidewall surface 318 extending upwards form the bottom surface 316 to the opening 314. It is contemplated that the bottom surface 316 of the recess 308 have a different crystalline structure than that of the sidewall surface 318 of the recess 308. In this respect the bottom surface 316 has a silicon 1 0 0 crystalline structure 320 and the sidewall surface 318 has a silicon 1 1 0 crystalline structure 322.

The recess 308 has a width 324 and a depth 326. In certain examples, the recess 308 may be a high aspect ratio recess. For example, an aspect ratio defined by the depth 326 and the width 324 may be greater than about 3:1, or greater than about 10:1, or greater than about 50:1, or even greater than about 100:1. The aspect ratio may be between about 3:1 and about 100:1. In accordance with certain examples, the recess may be a trench. It is also contemplated that the recess 308 may be a via, a contact, or any other recess suitable for forming the structure 300 (shown in FIG. 10). The recess 308 (shown in FIG. 5) may be formed using an etching technique, for example, subsequent to patterning the material layer surface 312 (shown in FIG. 5) to locate the opening 314 (shown in FIG. 5) of the recess 308 within the material layer 306.

As shown in FIG. 6, it is contemplated that a film 328 be deposited within the recess 308 using an epitaxial technique to form the structure 300. The film 328 is deposited within the recess 308 by flowing one or more the first precursor 142, the second precursor 146, the halide 152, and the purge/carrier gas 158 into the interior 130 of the reaction chamber 102 (shown in FIG. 1) to form the film 328. The film 328 is deposited such that the film 328 only partially occupies the recess 308, the film 308 in this respect having a bottom segment 330 and a sidewall segment 332 located within the 308. As will be appreciated by those of skill in the art in view of the present disclosure, the bottom segment 330 of the film 328 forms with a crystalline structure conforming to that of the bottom surface 316 of the recess 308, i.e., to the silicon 1 0 0 crystalline structure 320 of the bottom surface 316, and the sidewall segment 332 of the film 328 forms with a crystalline structure conforming to that of the sidewall surface 318 of the recess 308, i.e., to the silicon 1 1 0 crystalline structure 322 of the sidewall surface 318.

The film 328 may be deposited within the recess 308 by flowing dichlorosilane (DCS), hydrochloric acid (HCl), and hydrogen (H₂) gas through the interior 130 of the reaction chamber 102. The film 328 may be deposited within the recess 308 by maintaining at least one of a predetermined deposition pressure and a predetermined deposition temperature within the interior 130 of the reaction chamber 102 (shown in FIG. 1) during the deposition of the film 328. The predetermined deposition temperature may be between about 675° C. and about 850° C. The predetermined deposition pressure may be between about 1 torr and about 50 torr. As has been explained above, and as shown with chart A in FIG. 12, deposition temperatures and/or deposition pressures within these ranges allow the bottom segment 330 of the film 328 to be deposited onto the bottom surface 316 of the recess 308 more rapidly than the sidewall segment 332 of the film 328 is deposited onto the sidewall surface 318 of the recess 308, i.e., at a deposition rate ratio greater than 1:1. As will be appreciated by those of skill in the art in view of the present disclosure, deposition rate ratios greater than 1:1 can reduce the cycle time required to form the structure 300 (shown in FIG. 10) by reducing the number revisits to the reaction chamber to fill the recess 308, improving throughput of the semiconductor processing system employed to form the structure 300, e.g., the semiconductor processing system 100 (shown in FIG. 1). In certain examples, and as shown in FIG. 11, the deposition rate ratio may be between about 1.1:1 and about 2:1.

As shown in FIG. 7, it is contemplated that the sidewall segment 332 (shown in FIG. 6) of the film 328 (shown in FIG. 6) be removed from within the recess 308 while a portion of the bottom segment 330 (shown in FIG. 6) be retained within the recess 308. Removal may be accomplished by flowing at least one of the halide 152 and the purge/carrier gas 158 into the interior 130 of the reaction chamber 102 (shown in FIG. 1), the halide 152 and the purge/carrier gas 158 cooperating to etch the sidewall segment 332 and the bottom segment 330 of the film 328 from within the recess 308. It is contemplated that the halide 152 and the purge/carrier gas 158 remove substantially all of the sidewall segment 332 of the film 328 from within the recess 308. It is also contemplated that a retained portion 336 of the bottom segment 330 remain within the recess 308, the retained portion 336 presenting a 1 0 0 crystalline structure to the recess 308 at a fill surface 334.

The sidewall segment 332 (shown in FIG. 6) may be removed from the sidewall surface 318 and at least a portion of the bottom segment 330 (shown in FIG. 6) retained within the recess 308 by flowing hydrochloric acid (HCl) and hydrogen (H₂) gas through the interior 130 of the reaction chamber 102 (shown in FIG. 1). Removal may be accomplished by maintaining at least one of a predetermined removal temperature and a predetermined removal pressure within the interior 130 of the reaction chamber 102. The predetermined removal temperature may be between and 675° C. and about 850° C. The predetermined removal pressure may be between about 5 Torr and about 50 Torr. As has been explained above, and as shown with chart C in FIG. 13, removal temperatures and/or removal pressures within these ranges allow the sidewall segment 332 of the film 328 to be removed more rapidly than the bottom segment 330 of the film 328, i.e., at a removal rate ratio that is greater than 1, also reducing cycle time required to form the structure 300 (shown in FIG. 10) and improving of the semiconductor processing system used to form the structure 300, e.g., the semiconductor processing system 100 (shown in FIG. 1). In certain examples, the removal rate ratio may be between about 5:1 and about 25:1.

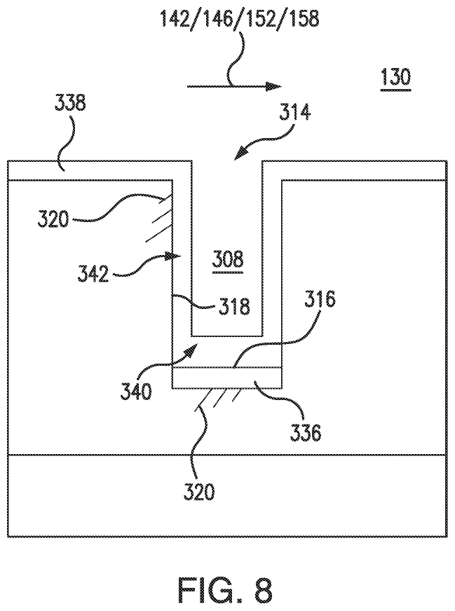

As shown in FIGS. 8 and 9, a second film 338 having a second film bottom segment 340 and a second film sidewall segment 342 is thereafter deposited within the recess 308, and the second film sidewall segment 342 removed while a portion of the second film bottom segment 340 retained within the recess 308. Referring to FIG. 7, it is contemplated that the film 328 (shown in FIG. 6) be a first film 328 with a first bottom segment 330 (shown in FIG. 6) and a first sidewall segment 332 (shown in FIG. 6), and that the second film 338 be deposited within the recess 308 and onto the retained portion 336 and the sidewall surface 318 of the recess 308. More specifically, the second film sidewall segment 342 of the second film 338 is deposited onto the sidewall surface 318 of the recess 308, and the second film bottom segment 340 is deposited onto the fill surface 334 of the retained portion 336 of the first film 328. It is contemplated that the second film 338 be deposited epitaxially, e.g., in a deposition operation similar (or identical) to the deposition operation used employed to deposit the first film 328, the second film bottom segment 340 thereby forming with a 1 0 0 crystalline structure conforming to the silicon 1 0 0 crystalline structure 320 of the bottom surface 316 of the recess 308, and the second film sidewall segment 342 thereby forming with a 1 1 0 crystalline structure conforming to the silicon 1 1 0 crystalline structure 322 of the sidewall surface 318 of the recess 308.

As shown in FIG. 9, the second film sidewall segment 342 (shown in FIG. 8) is thereafter removed and a portion of the second film bottom segment 340 (shown in FIG. 8) retained within the recess 308. As above, it is contemplated that the second film sidewall segment 342 be removed in its entirety and that a second retained portion 344 with a second fill surface 346 be retained within the recess 308. It is also contemplated that the second retained portion 344 be formed with a 1 0 0 crystalline structure conforming to that of the silicon 1 0 0 crystalline structure 320 of the bottom surface 316, and that the second retained portion 344 present the 1 0 0 crystalline structure to the recess 308 at the second fill surface 346. As will be appreciated by those of skill in the art in view of the present disclosure, as both the first retained portion 336 and the second retained portion 344 have a 1 0 0 crystalline structure conforming to that of the silicon 1 0 0 crystalline structure 320 of the bottom surface 316 of the recess, the resulting structure formed therefrom is substantially homogenous with respect to crystalline structure, e.g., has no 1 1 0 crystalline structure, limiting (or eliminating) the variation in electrical properties that could otherwise accompany such crystalline discontinuities within the structure.

As shown in FIG. 10, it is contemplated that the first retained portion 336 be deposited onto the bottom surface 316 of the recess 308 during a first deposition/removal cycle including a first deposition operation (shown in FIG. 6) and a first removal operation (shown in FIG. 7), that the second retained portion 344 be deposited onto the first retained portion 336 during a second deposition/removal cycle include a second deposition operation (shown in FIG. 8) and a second removal operation (shown in FIG. 9), and that recess 308 thereafter be filled from the bottom-up (as shown in FIG. 10). In this respect one or more additional retained portion 350 may be deposited onto a second fill surface 346 of the second retained portion 344 and/or a topping portion 348 deposited within the recess 308 and overlaying the bottom surface 316 of the recess 308 to form the structure 300. A semiconductor device 400, such as a finFET device or a gate-all-around device, may thereafter be formed overlaying the substrate 302 including the structure 300. Although the structure 300 is shown in FIG. 10 as including ten (10) retained portions it is to be understood and appreciated that the structure may include fewer or more retained portions and remain within the scope of the present disclosure.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

### PARTS LIST

100 Semiconductor Processing System
102 Reaction Chamber
104 Injection Header
106 Exhaust Header
108 Process Kit
110 Outer Ring
112 Susceptor
114 Susceptor Support Member
116 Shaft
118 Gas Delivery Arrangement
120 First Precursor Source
122 Second Precursor Source
124 Halide Source
126 Purge/Carrier Gas Source
128 Controller
130 Interior
132 Injection End
134 Exhaust End
136 Transmissive Material
138 One or More Heater Elements
140 Precursor Conduit
142 First Precursor
144 First Precursor MFC
146 Second Precursor
148 Second Precursor MFC
150 Halide Conduit
152 Halide
154 First Halide MFC
156 Second Halide MFC
158 Purge/Carrier Gas
160 First Purge/Carrier Gas MFC
162 Second Purge/Carrier Gas MFC
164 Opaque Material
166 Rotation Axis
168 Drive Module
170 Processor
172 Device Interface
174 User Interface
176 Memory
178 Program Modules
200 Method
210 Box
220 Box
221 Box
222 Box
223 Box
224 Box
225 Box
226 Box
228 Box
230 Box
231 Box
232 Box
233 Box
234 Box
235 Box
236 Box
237 Box
238 Box
239 Box
240 Arrow
250 Box
252 Box
254 Box
256 Box
260 Box
262 Box
264 Box
290 Box
300 Structure
302 Substrate
304 Surface
306 Material Layer
308 Recess
310 Silicon-Containing Material
312 Material Layer Surface
314 Opening
316 Bottom Surface
318 Sidewall Surface
320 1 0 0 Crystalline Structure
322 1 1 0 Crystalline Structure
324 Width
326 Depth
328 Film
330 Bottom Segment
332 Sidewall Segment
334 Fill Surface
336 Retained Portion
338 Second Film
340 Second Film Bottom Segment

1. A method of forming a structure, comprising:
supporting a substrate within a reaction chamber of a semiconductor processing system, wherein the substrate has a recess with a bottom surface and a sidewall surface extending upwards from the bottom surface of the recess;
depositing a film within the recess and onto the bottom surface and the sidewall surface of the recess, the film having a bottom segment overlaying the bottom surface of the recess and a sidewall segment deposited onto the sidewall surface of the recess;
removing the sidewall segment of the film while retaining at least a portion bottom segment of the film within the recess; and
wherein removing the film comprises removing the sidewall segment of the film from the sidewall surface more rapidly than removing the bottom segment of the film from the bottom surface of the recess.

2. The method of claim 1, wherein depositing the film comprises depositing the bottom segment of the film onto the bottom surface more rapidly than depositing the sidewall segment of the film onto the sidewall surface of the recess.

3. The method of claim 1, wherein the sidewall segment and the bottom segment of the film are removed at a removal rate ratio that is between 5:1 and 25:1.

4. The method of claim 1, wherein the bottom segment and the sidewall segment of the film are deposited at a deposition rate ratio that is between 1.1:1 and 2:1.

5. The method of claim 1, wherein the sidewall segment and the bottom segment of the film are removed at a predetermined removal pressure that is between 1 torr and 50 torr.

6. The method of claim 1, wherein the sidewall segment and the bottom segment of the film are removed at a predetermined removal temperature that is between 675° C. and 850° C.

7. The method of claim 1, wherein the sidewall segment and the bottom segment of the film are deposited at a predetermined deposition pressure that is between 1 torr and 50 torr.

8. The method of claim 1, wherein the sidewall segment and the bottom segment of the film are deposited at a predetermined deposition temperature that is between 675° C. and 850° C.

9. The method of claim 1, wherein the sidewall segment and the bottom segment of the film are deposited and removed at a common pressure, wherein the sidewall segment and the bottom segment of the film are deposited and removed at a common temperature.

10. The method of claim 1, further comprising flowing dichlorosilane (DCS), hydrochloric acid (HCl), and hydrogen (H₂) gas through an interior of the reaction chamber to deposit the sidewall segment and the bottom segment of the film into the recess.

11. The method of claim 1, further comprising flowing hydrochloric acid (HCl) and hydrogen (H₂) gas through an interior of the reaction chamber to remove the sidewall segment and a portion of the bottom segment of the film from within the recess.

12. The method of claim 1, wherein the bottom surface of the recess has a silicon 1 0 0 crystalline structure, wherein the sidewall surface of the recess has a silicon 1 1 0 crystalline structure.

13. The method of claim 1, wherein the deposition operation and the removal operation comprise a first deposition/removal cycle, the method further comprising at least one second deposition/removal cycle.

14. The method of claim 1, further comprising filling the recess bottom-up from the bottom surface of the recess to an opening into the recess.

15. The method of claim 1, wherein removing the sidewall segment from the sidewall surface comprises exposing the sidewall surface above a retained portion of the bottom segment of the film from within the recess.

16. A semiconductor processing system, comprising:
a reaction chamber;
a gas delivery arrangement connected to the reaction chamber; and
a controller including a non-transitory machine-readable memory and a processor operatively connected to the gas delivery arrangement, wherein the memory has a plurality of program modules recorded on the memory containing instructions that, when read by the processor, cause the processor to:
support a substrate within the reaction chamber, wherein the substrate has a recess with a bottom surface and a sidewall surface extending upwards from the bottom surface of the recess;
deposit a film within the recess and onto the bottom surface and the sidewall surface of the recess, the film having a bottom segment overlaying the bottom surface of the recess and a sidewall segment deposited onto the sidewall surface of the recess;
remove the sidewall segment of the film while retaining at least a portion bottom segment of the film within the recess; and
wherein the sidewall segment of the film is removed from the sidewall surface of the recess more rapidly than bottom segment of the film is removed from the bottom surface of the recess.

17. The system of claim 16, wherein the instructions further cause the controller to:
flow hydrochloric acid (HCl) and hydrogen (H₂) gas through an interior of the reaction chamber to remove the sidewall segment and a portion of the bottom segment of the film from within the recess;
flow dichlorosilane (DCS), hydrochloric acid (HCl), and hydrogen (H₂) gas through the interior of the reaction chamber to deposit the sidewall segment and the bottom segment of the film into the recess; and
wherein the bottom segment of the film is deposited onto the bottom surface of the recess more rapidly than the sidewall segment of the film is deposited onto the sidewall surface of the recess.

18. The system of claim 16, wherein the instructions further cause the controller to:
deposit the bottom segment and the sidewall segment of the film at a deposition rate ratio that is between 1.1:1 and 2:1; and
remove the bottom segment and the sidewall segment of the film at a removal rate ratio that is between 5:1 and 25:1.

19. The system of claim 16, wherein the instructions further cause the controller to:
deposit the sidewall segment and the bottom segment of the film at a predetermined deposition pressure that is between 1 torr and 50 torr;
deposit the sidewall segment and the bottom segment of the film at a predetermined deposition temperature that is between 675° C. and 850° C.
remove the sidewall segment and a portion of the bottom segment of the film at a predetermined deposition pressure that is between 1 torr and 50 torr;
remove the sidewall segment and the portion of the bottom segment of the film at a predetermined deposition temperature that is between 675° C. and 850° C.

20. A finFET or a gate-all-around semiconductor device comprising a structure formed using the method of claim 1.
